(19) United States
(12) Patent Application Publication
(10) Pub. No.: US 2006/0037738 A1
(43) Pub. Date: Feb. 23, 2006

(54) Heat-dissipating device with heat pipe

(75) Inventors: Chin-Yuan Li, Taipei (TW); Mao-Ching Lin, Taipei (TW)

Correspondence Address: EITAN, PEARL, LATZER & COHEN ZEDEK LLP, 10 ROCKEFELLER PLAZA, SUITE 1001, NEW YORK, NY, 10020, US

(73) Assignee: INVENTEC CORPORATION

(21) Appl. No.: 11/023,500

(22) Filed: Dec. 29, 2004

(30) Foreign Application Priority Data
Aug. 23, 2004 (TW) 093213390

(51) Int. Cl. H05K 7/20

(52) U.S. Cl. 165/104.33; 165/80.3; 361/700

(57) ABSTRACT

A heat-dissipating device with heat pipe includes a base having a plurality of pipe spaces therein; a plurality of heat pipes vertically mounted on the base and connected to the pipe spaces respectively; a working fluid filled in the pipe spaces; and a plurality of heat-dissipating fins attached to the plurality of heat pipes and spaced from each other by a predetermined distance. This heat-dissipating device can achieve heat dissipation without bending the heat pipes.

### RELATED APPLICATION DATA

The present application claims priority from prior Tiawanese application number 092313390 filed Aug. 23, 2004, incorporated by reference herein in its entirety.

### FIELD OF THE INVENTION

The present invention relates to heat-dissipating devices, and more particularly, to a heat-dissipating device with heat pipe, which is applicable to an electronic device.

### BACKGROUND OF THE INVENTION

Along with the globalization era, human's requirements of efficiency and convenience for working pace have become far more expected than the past. How to achieve multi-functionality of living needs within the most efficient timing becomes an important consideration for a consumer to purchase various living products in the market. For electronic products, a research and development trend thereof has aimed to produce new generation of products that are compact in size, have multiple functions and are highly efficient so as to satisfy the requirements of consumers in recent years.

Although the advanced semiconductor fabrication and IC (integrated circuit) design technologies have successfully reduced the size and improved the integration of electronic elements as well as provided multi-functional integration in the recent decade, there are still some new problems caused thereby, which are difficult to solve and would degrade reliability of the electronic elements. A reason may be the impossibility for the electronic elements, which require electric power to drive operation thereof, to reach 100% working efficiency, such that the wasted power is converted to heat energy and greatly increases an operating temperature of the entire system. If the operating temperature exceeds a tolerable range, errors would occur in the operation of such system; even worse, the system may fail or burn out due to overheat at the excessively high temperature. For the aforementioned new generation of electronic products with high density, internal electronic elements thereof have a much higher operating speed than those of the traditional products, such that a large amount of heat energy would be generated during operation and easily causes the operating temperature to exceed the tolerable range, making the system fail in operation.

In order to solve the above problem, a conventional strategy is to mount a heat-dissipating device with heat pipe on a high-temperature electronic device such as central processing unit (CPU), etc. As shown in FIG. 5A, the heat-dissipating device comprises a base 40 attached to the electronic device (not shown), a plurality of heat pipes 42 mounted to slots 41 on a surface of the base 40 and for conducting heat energy, and a plurality of heat-dissipating fins 45 arranged in parallel and at constant intervals therebetween and inserted on the heat pipes 42, so as to dissipate the heat energy through the heat-dissipating fins 45.

The above heat-dissipating device is characterized in that the heat pipes 42 are bent to have a U shape, wherein bottom horizontal portions 42a of the heat pipes 42 are received in the slots 41 on the surface of the base 40, and top horizontal portions 42b of the heat pipes 42 are inserted into and in contact with the heat-dissipating fins 45. A working fluid in the bottom horizontal portions 42a after absorbing heat (e.g. heat energy from the electronic device such as CPU) and evaporating can enter the top horizontal portions 42b and condenses, such that the heat carried by the working fluid is transmitted to the heat-dissipating fins 45 and dissipated by means of fans (not shown) or a natural thermal convection effect, making the working fluid circulate.

Alternatively, it may change the orientation of the U-shaped heat pipes. As shown in FIG. 5B, bottom horizontal portions 42c of the heat pipes 42 are received in the slots 41 on the surface of the base 40, and extensive vertical portions 42d of the heat pipes 42 at two sides are inserted into the heat-dissipating fins 45. Such shaped heat pipes 42 can also achieve heat transmission and dissipation. This heat-dissipating device with heat pipe has been disclosed in Taiwanese Patent Nos. 505379, 560835, 573930, and 581292, etc.

However, the above conventional heat-dissipating device still has significant drawbacks. This is because inner walls of the heat pipes 42 have a capillary structure, which sets a limitation on bending of the heat pipes 42, making the heat pipes 42 not able to be bent by an angle close to 90 degrees. A curvature radius R (see FIGS. 6A and 6B) has a minimum value in processing, and thus a surplus space K would be formed at the bending region; such surplus space K cannot accommodate the heat-dissipating fins 45 nor be received in the slots 41 of the base 40. This situation not only causes a waste of space for the heat pipes 42 but also affects the number of heat-dissipating fins 45 to be mounted and the size of an evaporation region for the heat pipes 42. Thereby, the heat dissipating performance of the heat-dissipating device is hard to be improved, and such heat-dissipating device fails to satisfy the heat dissipating requirements for the next generation of highly efficient electronic products.

Therefore, the problem to be solved here is to provide an improved heat-dissipating device with heat pipe, which can resolve a structural limitation caused by the pipe bending region and enhance the overall heat dissipating performance.

### SUMMARY OF THE INVENTION

In light of the foregoing drawbacks in the prior art, a primary objective of the present invention is to provide a heat-dissipating device with heat pipe, so as to enhance the heat dissipating performance.

Another objective of the present invention is to provide a heat-dissipating device with heat pipe, which can increase the number of heat-dissipating fins mounted therein.

Still another objective of the present invention is to provide a heat-dissipating device with heat pipe, which can enlarge an operation area of heat pipes.

In order to achieve the aforementioned and other objectives, the present invention proposes a heat-dissipating device with heat pipe, comprising: a base having at least one pipe space therein; a plurality of heat pipes vertically mounted on the base and connected to the pipe space respectively; a working fluid filled in the pipe space; and a plurality of heat-dissipating fins attached to the heat pipes and spaced from each other by a predetermined distance.

Alternatively, the heat-dissipating device according to the present invention comprises: a base having at least one pipe space therein; at least one heat pipe horizontally inserted in the pipe space; a working fluid filled in the pipe space; and a plurality of heat-dissipating fins attached to the heat pipe and spaced from each other by a predetermined distance.

Inner walls of the pipe space and heat pipe both have a capillary structure for enhancing the adhesion with the working fluid. The working fluid is one selected from the group consisting of liquid water, mercury, potassium, sodium, acetone, liquid nitrogen and alcohol.

Moreover, the heat pipe is bonded or welded to the base, and the plurality of heat-dissipating fins are spaced from each other by a constant distance and arranged on the heat pipe in parallel.

Therefore, the heat-dissipating device with heat pipe according to the present invention can achieve heat transmission through the heat pipe without bending the heat pipe, thereby avoiding a structural limitation caused by the conventional bent heat pipe and thus solving the problems incurred in the conventional heat-dissipating device with heat pipe.

### BRIEF DESCRIPTION OF THE DRAWINGS

The present invention can be more fully understood by reading the following detailed description of the preferred embodiments, with reference made to the accompanying drawings, wherein:

FIG. 1 is a schematic diagram of a heat-dissipating device with heat pipe in accordance with a first preferred embodiment of the present invention;

FIG. 2 is a cross-sectional diagram of the heat-dissipating device shown in FIG. 1;

FIG. 3 is a schematic diagram of a heat-dissipating device with heat pipe in accordance with a second preferred embodiment of the present invention;

FIG. 4 is a cross-sectional diagram of the heat-dissipating device shown in FIG. 3;

FIG. 5A (PRIOR ART) is a schematic diagram of a conventional heat-dissipating device with heat pipe;

FIG. 5B (PRIOR ART) is a schematic diagram of another conventional heat-dissipating device with heat pipe; and

FIGS. 6A and 6B (PRIOR ART) are schematic diagrams showing drawbacks of design for the conventional heat-dissipating devices shown in FIGS. 5A and 5B respectively.

### DETAILED DESCRIPTION OF THE PREFERRED EMBODIMENTS

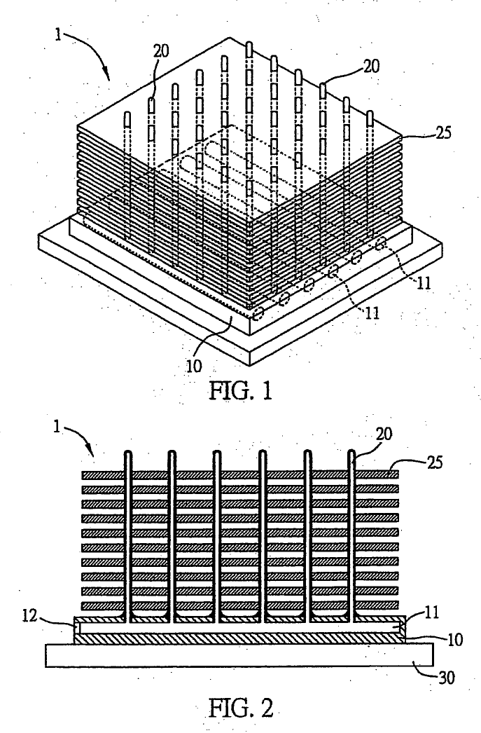

FIGS. 1 and 2 are schematic diagrams of a heat-dissipating device with heat pipe 1 according to a first preferred embodiment of the present invention, which comprises a base 10; a plurality of parallel pipe spaces 11 formed in the base 10 and penetrating at least one side of the base 10; a plurality of parallel heat pipes 20 vertically mounted on the base 10 and connected to the pipe spaces 11 respectively, such that each of the heat pipes 20 communicates with one of the pipe spaces 11, and the heat pipes 20 arranged in the same row communicate with the same single pipe space 11; and a plurality of heat-dissipating fins 25 attached to the heat pipes 20, wherein the heat-dissipating fins 25 are shaped as plates and are arranged on the heat pipes 20 in parallel and spaced from each other by a constant distance. Moreover, a working fluid (not shown) is filled in the pipe spaces 11 of the base 10, such that the working fluid when being evaporated by heat can enter inner spaces of the heat pipes 20.

Inner walls of the pipe spaces 11 and heat pipes 20 are formed with a slot-shaped capillary structure (not shown) for enhancing adhesion with and fluidity of the working fluid. The capillary structure is made using a boring cutter and is not particularly limited on the shape thereof. Moreover, the plurality of heat pipes 20 are vertically bonded or welded to the base 10, and the bonding or welding position is located at the periphery of a contact portion of each of the heat pipes 20 coming into contact with the base 10.

Once the working fluid is filled in the pipe spaces 11, a seal 12 such as a plate-shaped copper pillar is used to seal an opening of each of the pipe spaces 11. The type of working fluid depends on the application field of the heat-dissipating device 1 and can be determined by an environmental temperature and a boiling point of the working fluid. Generally, the working fluid is one selected from the group consisting of liquid water, mercury, potassium, sodium, acetone, liquid nitrogen and alcohol.

During operation of the heat-dissipating device 1 in the present invention, the base 10 of the heat-dissipating device 1 is mounted on and in contact with a heat source 30 such as an electronic device (see FIG. 2). Heat energy from the heat source 30 would be absorbed via thermal conductivity by the working fluid in the pipe spaces 11 of the base 10, and the working fluid in the pipe spaces 11 as being heated is evaporated to a gaseous state. The gaseous working fluid enters the plurality of heat pipes 20 connected to the pipe spaces 11, and condenses in the heat pipes 20 having a lower temperature than the base 10. As a result, the heat energy carried by the working fluid is conducted to the heat-dissipating fins 25 through the heat pipes 20, and can be dissipated from the heat-dissipating fins 25 by means of a fan (not shown) or a natural thermal convection effect, thereby achieving heat dissipation for the electronic device 30.

Furthermore, the working fluid condenses in the heat pipes 20 into liquid and thus falls from the capillary structure of the inner walls of the heat pipes 20 back to the pipe spaces 11 of the base 10, making the working fluid circulate and continuously absorb heat for a next cycle of heat dissipation.

Since the heat pipes 20 of the heat-dissipating device 1 in the present invention are not bent to have a U shape unlike the prior art and are maintained with a vertical structure, this simplifies the fabrication processes and reduces the cost as well as avoids a waste of space caused by the conventional pipe bending region. It is thus apparent that the heat-dissipating device in the present invention is able to accommodate more heat-dissipating fins than the conventional heat-dissipating device, and would not have a problem of decrease in an evaporation area of the working fluid due to the conventional bending heat pipes, such that the overall heat dissipating performance can be improved in the present invention.

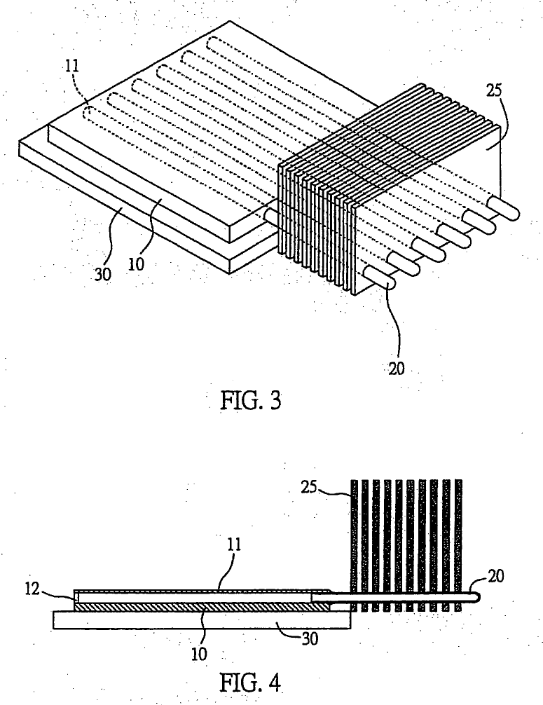

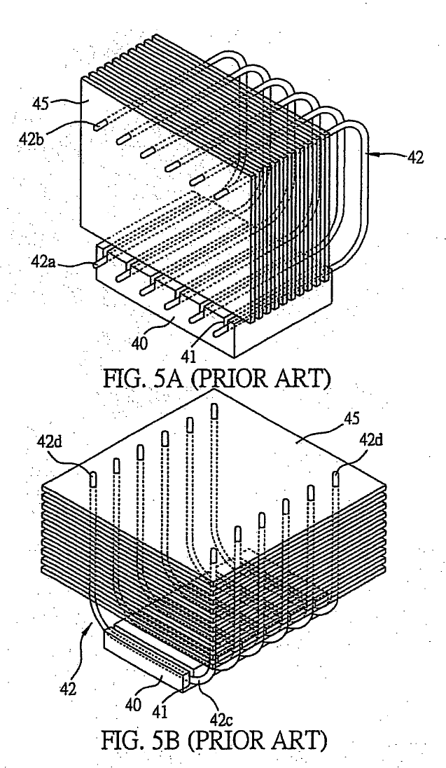

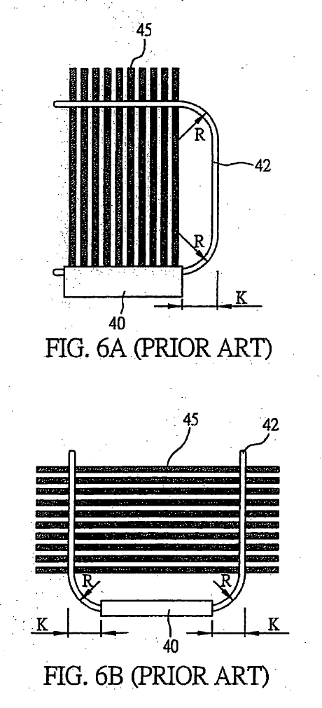

FIGS. 3 and 4 are schematic diagrams of the heat-dissipating device with heat pipe 1 according to a second preferred embodiment of the present invention. This second embodiment differs from the above first embodiment in that, the pipe spaces 11 penetrate two sides of the base 10, and the plurality of heat pipes 20 are horizontally bonded or welded to the base 10 and connected to the pipe spaces 11. That is, the heat pipes 20 are extended from the pipe spaces 11 and are coplanar with the pipe spaces 11, wherein each of the pipe spaces 11 is merely connected with one of the heat pipes 20.

Further, the pipe spaces 11 are similarly filled with the working fluid, and the heat-dissipating fins 25 are also attached to the heat pipes 20 and are arranged in parallel and spaced from each other by a constant distance. Moreover, a seal 12 is used to seal a free end of each of the pipe spaces 11 not connected with the corresponding heat pipe 20.

During operation of the heat-dissipating device 1, similarly the base 10 is mounted on a heat source 30 such as an electronic device (see FIG. 4), and the working fluid in the pipe spaces 11 absorbs heat energy from the heat source 30, allowing the heat energy to be conducted and dissipated through the heat pipes 20 and the heat-dissipating fins 25. Also in this embodiment, there is no need to bend the heat pipes 20, such that no surplus space would be formed due to bending of heat pipes, and the number of heat-dissipating fins 25 mounted in the heat-dissipating device 1 can be increased so as to enhance the overall heat dissipating performance.

Therefore, the heat-dissipating device with heat pipe according to the present invention can desirably achieve heat transmission through heat pipes without bending the heat pipes, and avoids a structural limitation caused by the conventional bent heat pipes, thereby solving the problems incurred in the conventional heat-dissipating device with heat pipe.

The present invention has been described using exemplary preferred embodiments. However, it is to be understood that the scope of the invention is not limited to the disclosed embodiments. On the contrary, it is intended to cover various modifications and similar arrangements. The scope of the claims, therefore, should be accorded the broadest interpretation so as to encompass all such modifications and similar arrangements.

What is claimed is:

1. A heat-dissipating device with heat pipe, comprising:
a base having at least one pipe space therein;
a plurality of heat pipes vertically mounted on the base and connected to the pipe space respectively;
a working fluid filled in the pipe space; and
a plurality of heat-dissipating fins attached to the plurality of heat pipes and spaced from each other by a predetermined distance.

2. The heat-dissipating device with heat pipe of claim 1, wherein the working fluid is one selected from the group consisting of liquid water, mercury, potassium, sodium, acetone, liquid nitrogen and alcohol.

3. The heat-dissipating device with heat pipe of claim 1, wherein the base is formed with a plurality of the pipe spaces arranged in parallel therein.

4. The heat-dissipating device with heat pipe of claim 1, wherein an inner wall of the pipe space has a capillary structure.

5. The heat-dissipating device with heat pipe of claim 1, wherein an inner wall of each of the heat pipes has a capillary structure.

6. The heat-dissipating device with heat pipe of claim 1, wherein the heat pipes are welded to the base.

7. The heat-dissipating device with heat pipe of claim 1, wherein the plurality of heat pipes are arranged in parallel.

8. The heat-dissipating device with heat pipe of claim 1, wherein the plurality of heat-dissipating fins are spaced from each other by a constant distance.

9. The heat-dissipating device with heat pipe of claim 1, wherein the plurality of heat-dissipating fins are arranged in parallel.

10. A heat-dissipating device with heat pipe, comprising:
a base having at least one pipe space therein;
at least one heat pipe horizontally connected to the pipe space;
a working fluid filled in the pipe space; and
a plurality of heat-dissipating fins attached to the heat pipe and spaced from each other by a predetermined distance.

11. The heat-dissipating device with heat pipe of claim 10, wherein the working fluid is one selected from the group consisting of liquid water, mercury, potassium, sodium, acetone, liquid nitrogen and alcohol.

12. The heat-dissipating device with heat pipe of claim 10, wherein the base is formed with a plurality of the pipe spaces arranged in parallel therein.

13. The heat-dissipating device with heat pipe of claim 10, wherein an inner wall of the pipe space has a capillary structure.

14. The heat-dissipating device with heat pipe of claim 10, wherein an inner wall of the heat pipe has a capillary structure.

15. The heat-dissipating device with heat pipe of claim 10, wherein the heat pipe is horizontally inserted into the pipe space of the base.

16. The heat-dissipating device with heat pipe of claim 10, wherein the heat pipe is welded to the base.

17. The heat-dissipating device with heat pipe of claim 10, wherein the plurality of heat-dissipating fins are spaced from each other by a constant distance.

18. The heat-dissipating device with heat pipe of claim 10, wherein the plurality of heat-dissipating fins are arranged in parallel.
